(19) United States
(12) Patent Application Publication
(10) Pub. No.: US 2024/0238892 A1
(43) Pub. Date: Jul. 18, 2024

(54) METHOD FOR FORMING A MATERIAL-LOCKING CONNECTION

(71) Applicant: Robert Bosch GmbH, Stuttgart (DE)

(72) Inventors: Jens Trittel, Eisenach (DE); Ronny Wolf, Eisenach (DE)

(21) Appl. No.: 18/401,882

(22) Filed: Jan. 2, 2024

(30) Foreign Application Priority Data
Jan. 12, 2023 (DE) 10 2023 200 233.7

(51) Int. Cl. B23K 11/36; B23K 11/11

(52) U.S. Cl. CPC B23K 11/362; B23K 11/115

(57) ABSTRACT

A method for forming a material-locking connection between a first element formed of copper with a thickness of less than or equal to 70 micrometers with a second element formed of copper or aluminum and a thickness of greater than or equal to 800 micrometers by means of resistance welding, wherein, to form the material-locking connection between a first electrode, in particular a positive electrode, and a second electrode, in particular a negative electrode, an electrical current flows, such that the first element and the second element are connected in a material-locking fashion in a connection area, while a force is applied on the connection area at least with a contact area of the first electrode wherein the contact area of the first electrode is rounded.

### BACKGROUND

The invention proceeds from a method for forming a material-locking connection.

From the prior art, the formation of material-locking connections of two copper alloys with comparable similar thicknesses of the components by means of resistance welding and the formation of material-locking connections of two thin films with comparable similar thicknesses by means of ultrasonic welding are known.

The prior art includes, e.g., publications DE 10 2013 211 596 or DE 10 2018 117 601.

### SUMMARY

A method for forming a material-locking connection offers the advantage that a material-locking connection of two elements can be formed with comparatively significantly different material thicknesses by means of resistance welding. In particular, by avoiding the use of ultrasonic welding, the weldability of comparatively sensitive electronic elements can also be enabled.

According to the present invention, a method for forming a material-locking connection between a first element and a second element is provided for this purpose.

In this case, a first element is formed from copper and has a thickness less than or equal to 70 micrometers. Furthermore, the second element is formed from aluminum and has a thickness of greater than or equal to 800 micrometers. The first element and the second element are connected together by means of resistance welding in a materially-locking manner.

To form the material-locking connection between the first element and the second element, an electrical current flows between a first electrode, in particular a positive electrode, and a second electrode, in particular a negative electrode. In this case, the electrical current flows in such a way that the first element and the second element are connected in a material-locking manner in a connection area. The material-locking connection is formed while a force is applied to the connection area at least with a contact area of the first electrode. Furthermore, the contact area of the first electrode is rounded.

At this point, it is noted that in a resistive welding, two electrically conductively formed elements are connected to one another based on the Joule current heat of the electrical current flowing through the connection area. For this purpose, the two elements are heated as connecting partners until the respective welding temperature is reached and welded together in the connection area under the effect of force by solidification of the liquid phase such as a melt, by diffusion, or also in a solid phase.

In particular, flexible printed circuit boards, which may also be referred to as flexfilm or FFC for short, can be reliably connected by means of resistive welding in a material-locking manner. Flexible printed circuit boards comprise at least two films, between which electrical conductor paths, which are preferably formed from copper, are arranged. In particular, flexible printed circuit boards are flexible, deformable, or elastic.

It is advantageous if the first element is formed as a copper film. In particular, travel or arrival of the copper film can be avoided in this case by means of a method according to the invention, which in particular comprises a rounded contact area of the first electrode. It can be noted that the copper film can in particular also be the electrical conductor path of a flexible printed circuit board.

According to a first preferred aspect of the invention, the first element has a thickness of less than or equal to 50 micrometers. Furthermore, the second element is formed from copper having a thickness of greater than or equal to 800 micrometers. In particular, the second element is designed as a power bus. Power buses may comprise, for example, cell connectors or also voltage taps of battery cells or battery modules.

For the first preferred aspect of the invention, it is advantageous for the first electrode to be arranged on the first element and for the second electrode to be arranged on the second element. Furthermore, the first electrode and the second electrode are arranged oppositely and each apply a force on the connection area.

Furthermore, for the first preferred aspect of the invention, it is expedient on the one hand if a flow of the electrical current between the first electrode and the second electrode for forming the material-lock connection is less than 500 milliseconds, in particular less than 100 milliseconds, and between 750 amperes and 1250 amperes, in particular 950 amperes. Furthermore, the force on the connection area is selected to be less than 50 Newtons, in particular 30 Newtons.

In particular, this can preferably form a resistance spot welding method. For example, a flexible printed circuit board could hereby be connected to a voltage tap of a battery module or an electronic connection of a battery module in a material-locking manner. In particular, the electrical conductor paths of the flexible printed circuit board, which are preferably formed from copper, have a thickness of 35 micrometers. Furthermore, the cycle time per weld point is below one second. Furthermore, it should be noted at this point that the flexible printed circuit board can preferably be glued to the second element prior to the formation of the material-locking connection. In particular, the material-locking connection can be formed by means of a motorized weld gun.

Furthermore, for the first preferred aspect of the invention, it is further expedient if a flow of the electrical current between the first electrode and the second electrode for forming the material-lock connection is less than 500 milliseconds, in particular less than 200 milliseconds, and between 1500 amperes and 2500 amperes, in particular 2000 amperes. Furthermore, the force on the connection area is selected to be less than 100 Newtons, in particular 60 Newtons or 70 Newtons.

In particular, this can preferably form a resistance gap welding method. For example, a flexible printed circuit board could hereby be connected to a voltage tap of a battery module or an electronic connection of a battery module in a material-locking manner. In particular, the electrical conductor paths of the flexible printed circuit board, which are preferably formed from copper, have a thickness of 70 micrometers. Furthermore, it should be noted at this point that the flexible printed circuit board can preferably be glued to the second element prior to the formation of the material-locking connection. In particular, the material-locking connection can be formed by means of two pneumatic welding heads.

According to a second preferred aspect of the invention, the first element has a thickness of less than or equal to 70 micrometers. Furthermore, the second element is formed from aluminum having a thickness of greater than or equal to 2000 micrometers. In particular, the second element is designed as a die casting. For example, the second element could be a housing of a battery module.

Very preferably, a weld connection between the first element formed from copper and the second element formed from aluminum can be provided by means of resistance welding.

For the second preferred aspect of the invention, it is advantageous for the first electrode and the second electrode to be arranged on the first element. Furthermore, the first electrode and the second electrode are arranged next to each other and each applies a force on the connection area. In particular, the first electrode and the second electrode are arranged adjacent to each other on the first element.

Furthermore, for the second preferred aspect of the invention, it is expedient if a flow of the electrical current between the first electrode and the second electrode for forming the material-lock connection is less than 500 milliseconds, in particular less than 200 milliseconds and between 1500 amperes and 3500 amperes, in particular 2500 amperes. Furthermore, the force on the connection area is selected to be less than 100 Newtons, in particular 80 Newtons or 90 Newtons.

In particular, this can preferably form a resistance gap welding method. For example, a flexible printed circuit board could hereby be connected to a housing of a battery module in a material-locking manner. In particular, the electrical conductor paths of the flexible printed circuit board, which are preferably formed from copper, have a thickness of 70 micrometers. Furthermore, it should further be noted at this point that the flexible printed circuit board can preferably be glued to the second element prior to the formation of the material-locking connection. In particular, the material-locking connection can be formed by means of two pneumatic welding heads.

Overall, it is also expedient for the second preferred aspect of the invention if a eutectic material is formed to form the material-locking connection. In this respect, the welding process or method according to the invention for forming the material-locking connection between the first element and the second element is to be controlled such that at the same time both a contact surface of the first element formed from copper with a higher melting point and a contact surface of the second element formed from aluminum with a lower melting point are in the liquid phase. In particular, the method can be configured as a so-called gap welding method.

It can also be seen that the contact area of the first electrode is spherical with a defined radius. By means of such a configuration, a gap-free pressing of the first element, which is preferably configured as a copper film, can be provided against the second element by means of the first electrode and optionally also the second electrode, which can also have a rounded contact area, which can also preferably be spherical with a defined radius. In particular, no additional so-called hold-down is required.

In particular, the radius can be selected in such a way that it can be adjusted to the thickness of the first element and the second element.

### BRIEF DESCRIPTION OF THE DRAWINGS:

Exemplary embodiments of the invention are illustrated in the drawings and explained in greater detail in the subsequent description.

Shown are:

FIG. 1 a first embodiment of a method according to the invention for forming a material-locking connection, and

FIG. 2 a second embodiment of a method according to the invention for forming a material-locking connection.

### DETAILED DESCRIPTION

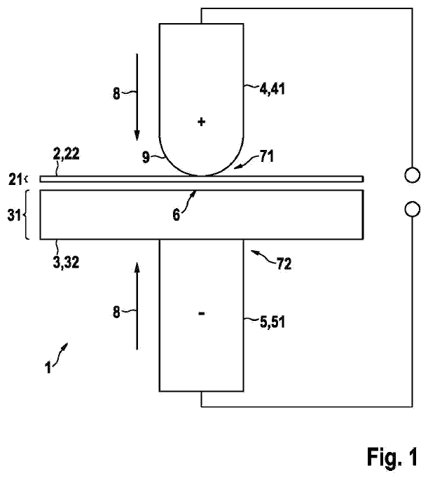

FIG. 1 shows a first embodiment of a method according to the invention for forming a material-locking connection 1.

Thereby a first element 2 can be seen, which is formed from copper and which has a thickness 21, which is less than or equal to 70 micrometers. Preferably, the first element 2 has a thickness 21 of less than or equal to 50 micrometers. In particular, the first element 2 is configured as a copper film 22.

In this case, a second element 3 can be seen which is also formed from copper and which has a thickness 31, which is greater than or equal to 800 micrometers. In particular, the second element 3 is designed as a power bus 32.

The first element 2 and the second element 3 are connected together by means of resistance welding in a materially-locking manner.

In addition, a first electrode 4, in particular a positive electrode 41, and a second electrode 5, in particular a negative electrode 51, can be seen.

To form the material-locking connection 1, an electrical current flows between the first electrode 4 and the second electrode 5 in such a way that the first element 2 and the second element 3 can be connected to each other in a material-locking manner in a connection area 6.

The first electrode 4 is arranged on the first element 2 and the second electrode 5 is arranged on the second element 3. In this case, the first electrode 4 and the second electrode 5 are arranged opposite to each other.

At the same time, a force 8 is applied on the connection area 6 with a contact area 71 of the first electrode 4. Furthermore, at the same time, a force 8 is applied on the connection area 6 with a contact area 72 of the second electrode 5. It can additionally be seen that the contact area 71 of the first electrode 4 is rounded.

It can also be seen that the contact area 71 of the first electrode 4 is spherical with a defined radius 9.

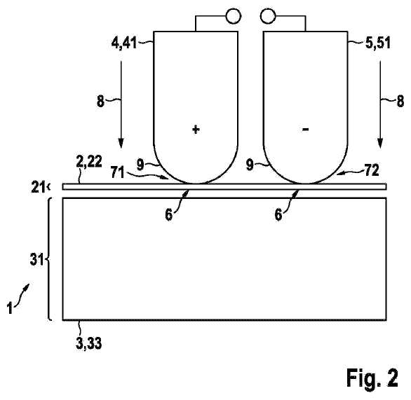

FIG. 2 shows a second embodiment of a method according to the invention for forming a material-locking connection 1.

Thereby a first element 2 can be seen, which is formed from copper and which has a thickness 21, which is less than or equal to 70 micrometers. In particular, the first element 2 is configured as a copper film 22.

Furthermore, a second element 3 can be seen, which is formed from aluminum and which has a thickness 31, which is greater than or equal to 2000 micrometers. In particular, the second element 3 is designed as a die casting 33.

The first element 2 and the second element 3 are connected together by means of resistance welding in a materially-locking manner.

In addition, a first electrode 4, in particular a positive electrode 41, and a second electrode 5, in particular a negative electrode 51, can be seen.

To form the material-locking connection 1, an electrical current flows between the first electrode 4 and the second electrode 5 in such a way that the first element 2 and the second element 3 can be connected to each other in a material-locking manner in a connection area 6.

The first electrode 4 and the second electrode 5 are arranged on the first element 2. In this case, the first electrode 4 and the second electrode 5 are arranged next to each other.

At the same time, a force 8 is applied on the connection area 6 with a contact area 71 of the first electrode 4. Furthermore, at the same time, a force 8 is applied on the connection area 6 with a contact area 72 of the second electrode 5. It can also be seen that the contact area 71 of the first electrode 4 and the contact area 72 of the second electrode 5 are rounded.

It can be seen that the contact area 71 of the first electrode 4 and the contact area 72 are spherical with a defined radius 9.

1. A method for forming a material-locking connection (1) between a first element (2) formed of copper
and having a thickness (21) of less than or equal to 70 micrometers with a second element (3) formed of copper or aluminum
and having a thickness (31) of greater than or equal to 800 micrometers by means of resistance welding, wherein
for forming the material-locking connection (1) between
a first electrode (4), and
a second electrode (5),
an electrical current flows in such a way that
the first element (2) and the second element (3) are connected in a material-locking manner
in a connecting area (6),
while a force (8) is applied on the connection area (6) at least with a contact area (71) of the first electrode 4, wherein
the contact area (71) of the first electrode (4) is rounded.

2. The method according to claim 1,
wherein
the first element (2) is formed as a copper film (22).

3. The method according to claim 1,
wherein
the first element (2)
has a thickness (21) of less than or equal to 50 micrometers, and in that the second element (3) is formed from copper
having a thickness (21) of greater than or equal to 800 micrometers.

4. The method according to claim 3,
wherein
the first electrode (4) is arranged on the first element (2) and
the second electrode (5) is arranged on the second element (3),
wherein the first electrode (4) and the second electrode (5) are arranged oppositely and
each apply a force (8) on the connection area (6).

5. The method according to claim 3,
wherein
a flow of the electrical current between
the first electrode (4) and the second electrode (5)
for forming the material-locking connection (1) is less than 500 milliseconds, and
between 750 amperes and 1250 amperes, and
the force (8) on the connection area (6) is selected to be less than 50 Newtons.

6. The method according to claim 3,
wherein
a flow of the electrical current between
the first electrode (4) and the second electrode (5)
for forming the material-locking connection (1)
is less than 500 milliseconds, and
between 1500 amperes and 2500 amperes, and
the force (8) on the connection area (6) is selected to be less than 100 Newtons.

7. The method according to claim 1,
wherein
the first element (2) has a thickness (21) of less than or equal to 70 micrometers and that
the second element (3) is formed from aluminum,,
having a thickness (31) of greater than or equal to 2000 micrometers.

8. The method according to claim 7,
wherein
the first electrode (4) and the second electrode (5)
are arranged next to each other on the first element (2) and each apply a force (8) on the connection area (6).

9. The method according to claim 7,
wherein
a flow of the electrical current between
the first electrode (4) and the second electrode (5) for forming the material-locking connection (1)
is less than 500 millisecond,, and between 1500 amperes and 3500 amperes, and
the force (8) on the connection area (6) is selected to be less than 100 Newtons.

10. The method according to claim 7,
wherein
a eutectic material is formed to form the material-locking connection (1).

11. The method according to claim 1,
wherein
the contact area (71) of the first electrode (4) is spherical with a defined radius 9.
